(19) United States
(12) Patent Application Publication
(10) Pub. No.: US 2007/0254470 A1
(43) Pub. Date: Nov. 1, 2007

(54) Method for fabricating a semiconductor device having a repair fuse

(75) Inventor: Jin-Ki Jung, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Hynix Semiconductor Inc.

(21) Appl. No.: 11/645,760

(22) Filed: Dec. 27, 2006

(30) Foreign Application Priority Data
Apr. 27, 2006 (KR) 2006-0038275
Dec. 12, 2006 (KR) 2006-0126367

(51) Int. Cl. H01L 21/4763

(52) U.S. Cl. 438/624

(57) ABSTRACT

A method for fabricating a semiconductor device is provided. The method includes forming a repair fuse over a substrate, forming an insulation layer over the repair fuse and the substrate, forming a metal line for use as a pad over the insulation layer, the metal line including a first metal layer and a second metal layer in a stack structure, forming a passivation layer over the substrate structure, forming a mask pattern for forming a pad open region and a fuse open region, etching the passivation layer and the insulation layer using a gas mixture that causes the insulation layer to remain over the repair fuse with a predetermined thickness and generates a polymer over the second metal layer, removing the polymer, and etching the second metal layer.

### RELATED APPLICATIONS

The present invention claims the benefit of priority of Korean patent application numbers 10-2006-0038275 and 10-2006-0126367, filed on Apr. 27, 2006 and Dec. 12, 2006, respectively, which are incorporated by reference in their entirety.

### BACKGROUND

The present invention relates to a method for fabricating a semiconductor device, and more particularly, to a method for fabricating a semiconductor device having a repair fuse.

A fuse has typically been used to repair a failure which has occurred in a semiconductor device. Typically, such fuses have not been formed through an additional process. The fuse has been formed using a conductive layer configuring a bit line, a word line, or a plate line of a capacitor. Typically, a repair open region including a thin insulation layer is formed over the repair fuse. Also, the semiconductor device includes a pad open region for wire bonding. When fabricating such semiconductor device, the repair open region and the pad open region may be formed at the same time using the same mask and etch process, or may be formed separately using different masks and etch processes.

FIGS. 1A and 1B illustrate cross-sectional views of a conventional method for fabricating a semiconductor device having a repair fuse. A repair open region and a pad open region are separately formed using different masks and etch processes.

Referring to FIG. 1A, a first insulation layer 12 is formed over a semi-finished substrate 11 including dynamic random access memories (DRAM). A first metal line 13A is formed on first insulation layer 12 in a pad region. For instance, first metal line 13A may include a metal layer such as an aluminum layer. Meanwhile, the metal layer used as first metal line 13A is also formed in a fuse region of the substrate structure as repair fuses 13B. A patterned second insulation layer 14, a via contact 15, a second metal line 100, a patterned oxide-based layer 18, and a patterned nitride-based layer 19 are formed over first metal line 13A, repair fuses 13B, and first insulation layer 12.

In more detail, a second insulation layer is formed over the resultant substrate structure. Via contact 15 is formed in a selected portion of second insulation layer. Second metal line 100 is formed on second insulation layer such that second metal line 100 and via contact 15 are coupled. Second metal line 100 includes a stack structure comprising an aluminum (Al) layer 16, and a titanium nitride (TiN) layer 17 stacked on Al layer 16. An oxide-based layer and a nitride-based layer are formed as a passivation layer on the resultant substrate structure.

A fuse mask etching process is performed on the substrate structure to form a fuse open region 20. During the fuse mask etching process, nitride-based layer, oxide-based layer, and second insulation layer are etched to form patterned nitride-based layer 19, patterned oxide-based layer 18, and patterned second insulation layer 14. The fuse mask etching process is performed until second insulation layer remaining on repair fuses 13B reaches a thickness of approximately 300 nm to 500 nm.

Referring to FIG. 1B, a pad mask etching process then is performed to form a pad open region 21. During the pad mask etching process, patterned nitride-based layer 19, patterned oxide-based layer 18, and TiN layer 17 are etched to expose Al layer 16, thereby forming a nitride-based pattern 19A, an oxide-based pattern 18A, a patterned TiN layer 17A, and an exposed Al layer 16A. Reference numeral 100A represents a patterned second metal line.

As describe above, the metal line formed over a plate line has been used as the fuse for highly integrated devices. Also, the fuse open region and the pad open region have been formed using separate mask etching processes. When using the metal line as the fuse, the pad open region and the fuse open region may have to be formed using separate masks and etch processes, because a failure may be generated at the pad open region due to a lack of an etch target.

In more detail, if a different bottom conductive layer, e.g., a bit line conductive layer or a conductive layer for use in a capacitor electrode, below the first metal line is used as a fuse, the etched thickness of the insulation layer for forming the fuse open region may become large. Thus, one mask may be used because the TiN layer of the pad open region may be sufficiently exposed due to a sufficient etch target. However, when the metal layer for use as the first metal line is used as the fuse, the etched thickness of the insulation layer for forming the fuse open region becomes relatively small. Thus, a failure may occur at the pad open region due to a lack of an TiN etch target. Accordingly, the conventional method uses separate mask processes.

However, when using two masks, two separate photolithography processes are usually required. Thus, the process may become complicated, production costs may increase, and production speed may decrease. Even if the metal layer for use as the first metal line is not used as the fuse, the aforementioned limitation may occur when the pad open region is formed using the insulation layer having a small thickness for forming the fuse open region.

### SUMMARY

Consistent with the present invention, there is provided a method for fabricating a semiconductor device, which can form a fuse open region and a pad open region using one mask even when an insulation layer for forming the fuse open region has a small etch thickness.

In one aspect, there is provided a method for fabricating a semiconductor device, including: forming a repair fuse over a substrate; forming an insulation layer over the repair fuse and the substrate; forming a metal line for use as a pad over the insulation layer, the metal line including a first metal layer and a second metal layer in a stack structure; forming a passivation layer over the substrate structure; forming a mask pattern for forming a pad open region and a fuse open region; etching the passivation layer and the insulation layer using a gas mixture that causes the insulation layer to remain over the repair fuse with a predetermined thickness and generates a polymer over the second metal layer; removing the polymer; and etching the second metal layer.

### BRIEF DESCRIPTION OF THE DRAWINGS

FIGS. 1A and 1B illustrates cross-sectional views showing a conventional method for fabricating a semiconductor device having a repair fuse.

FIGS. 2A to 2D illustrate cross-sectional views of a method for fabricating a semiconductor device having a repair fuse in accordance with an embodiment consistent with the present invention.

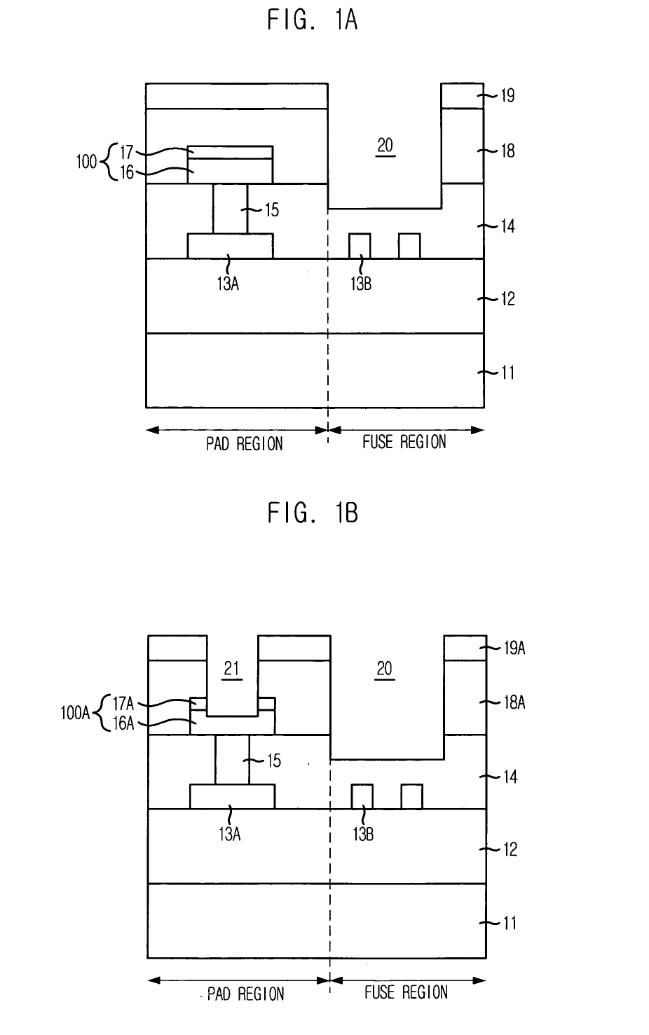

### DETAILED DESCRIPTION

In one embodiment consistent with the present invention, a fuse open region and a pad open region may be formed using one time of a photo masking process even if there is a lack of a margin of an etch target. Thus, process time and costs may decrease.

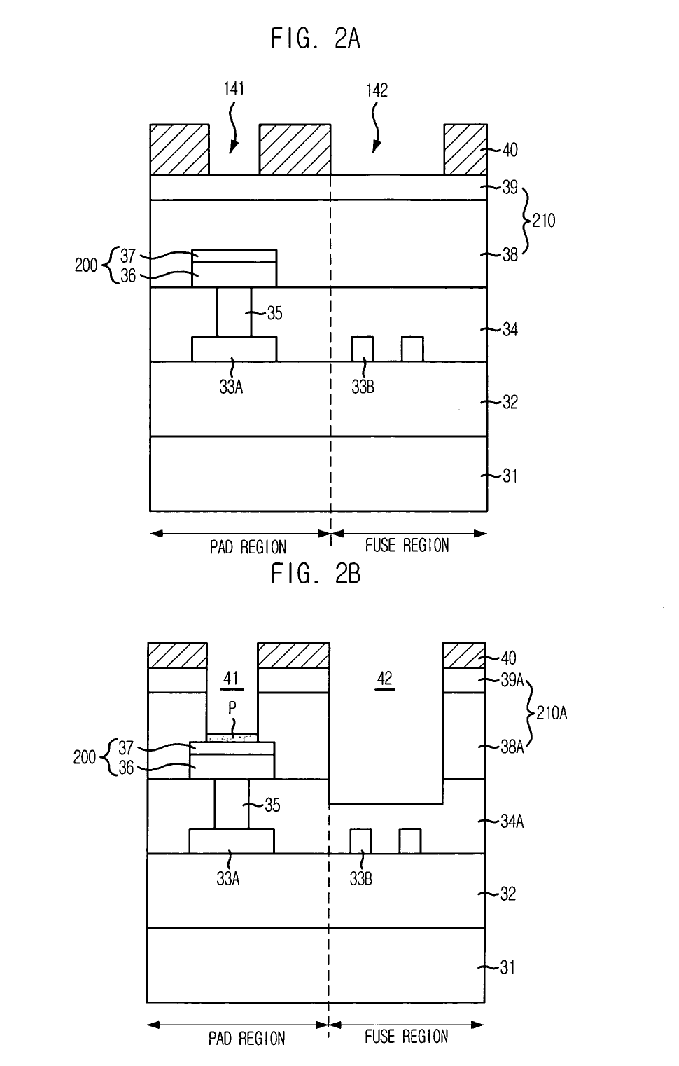

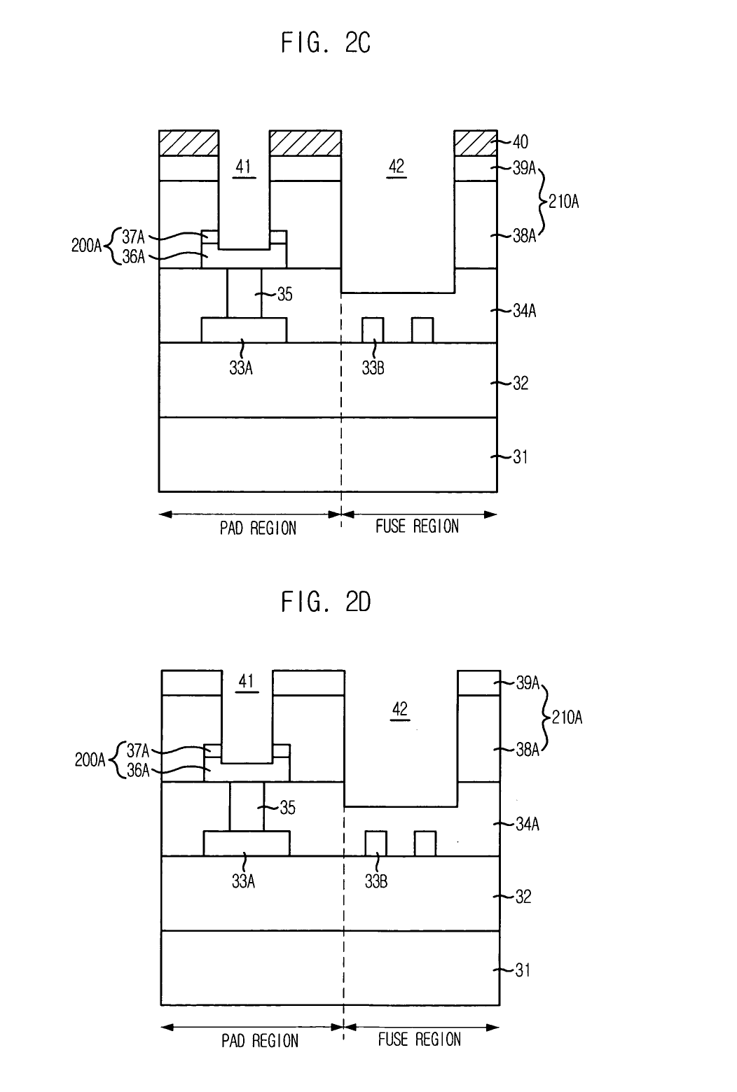

FIGS. 2A to 2D illustrate cross-sectional views of a method for fabricating a semiconductor device having a repair fuse in accordance with an embodiment consistent with the present invention.

Referring to FIG. 2A, a first insulation layer 32 is formed over a semi-finished substrate 31 that may include dynamic random access memories (DRAM). A first metal line 33A is formed in a pad region over first insulation layer 32. For instance, first metal line 33A may include a metal layer such as an aluminum layer. Meanwhile, repair fuses 33B are formed in a fuse region of the substrate structure, wherein repair fuses 33B may also be formed of a metal layer, such as aluminum. It is appreciated that first metal line 33A and repair fuses 33B may be formed in the same process or in different processes.

A second insulation layer 34 is formed over the resultant substrate structure. In more detail, a second insulation material layer is formed over the resultant substrate structure. A via contact 35 is formed in a selected portion of second insulation material layer, thereby forming second insulation layer 34. Second insulation layer 34 may include an oxide-based material. A second metal line 200 is formed over second insulation layer 34 such that via contact 35 and second metal line 200 are coupled. Second metal line 200 may include a stack structure configured with an aluminum (Al) layer 36 and a titanium nitride (TiN) layer 37. A passivation layer 210 including an oxide-based layer 38 and a nitride-based layer 39 is formed over the resultant substrate structure. Passivation layer 210 may include a single layer or layers of an oxide-based material and a nitride-based material, instead of a stack structure including oxide-based layer 38 and nitride-based layer 39.

A mask pattern 40 is formed over nitride-based layer 39 to form a first open region 141 and a second open region 142. Mask pattern 40 may include a photoresist pattern or a sacrificial hard mask pattern. In this embodiment, the photoresist pattern is used as mask pattern 40.

Referring to FIG. 2B, passivation layer 210 including nitride-based layer 39 and oxide-based layer 38, and second insulation layer 34 are etched using mask pattern 40 as an etch barrier to form a pad open region 41 and a fuse open region 42 corresponding to first open region 141 and second open region 142, respectively. Reference denotations 210A and 34A refer to a patterned passivation layer 210A including a patterned nitride-based layer 39A and a patterned oxide-based layer 38A, and a patterned second insulation layer 34A, respectively. The etching process is performed using a gas mixture that allows having second insulation layer 34 remain over repair fuses 33B with a predetermined thickness and generates polymer P over TiN layer 37.

In more detail, an etch gas may include a gas mixture comprising tetrafluoromethane (CF₄), fluoroform (CHF₃), and argon (Ar). A ratio of CF₄ to CHF₃ in the gas mixture, excluding Ar, may be less than approximately 4:1, i.e., CF₄:CHF₃<4:1. Such a ratio is used to generate a large amount of polymer in order to reduce a rapid increase of an etch rate of second insulation layer 34 in the repair etching. Also, the polymer generation may be induced using a gas including a high carbon/fluorine ratio instead of the gas mixture including CF₄, CHF₃, and Ar.

Referring to FIG. 2C, the remaining polymer P is removed using oxygen (O₂) gas. TiN layer 37 is etched until Al layer 36 is exposed. Reference denotations 37A, 36A, and 200A represent a patterned TiN layer 37A, a patterned Al layer 36A, and a patterned second metal line 200A, respectively. Patterned Al layer 36A exposed in pad open region 41 is a portion predetermined for wire bonding in a subsequent package process. TiN layer 37 may be etched using a gas including chlorine (Cl₂). For instance, a plasma etch using a mixed gas including Cl₂/trichloroborane (BCl₃) or Cl₂/Ar may be used. Patterned second insulation layer 34A including an oxide-based material suffers almost no loss during the plasma etch using the mixed gas including Cl₂.

Referring to FIG. 2D, an O₂ plasma removal process is performed to remove mask pattern 40. A wet cleaning process is performed to remove residues of the processes, and thus, formation of pad open region 41 and fuse open region 42 may be completed.

Meanwhile, although not illustrated, nitride-based spacers may be formed over sidewalls of pad open region 41 and fuse open region 42 for additional passivation. The spacers are provided to reduce absorption of moisture or impurities into the sidewalls. As a subsequent process, a pix layer for chip protection may be formed, and the pix layer may be densified by performing a thermal process. The pix layer includes carbon, and functions to protect a chip from X-ray and other interfering contaminants streaming from an external environment.

In this embodiment consistent with the present invention, mask pattern 40 may be removed also when removing polymer P. That is, even if mask pattern 40 including photoresist does not exist during the subsequent etching of TiN layer 37, the plasma etch including Cl₂ almost does not cause loss of passivation layer 210A including the oxide-based material and the nitride-based material, and patterned second insulation layer 34A.

Although repair fuses 33B are formed using the metal layer for use as a bottom metal line in a multiple layer metallization (MLM) structure in this embodiment, other conductive layers may be used instead of the bottom metal line. For instance, a bit line conductive layer or a conductive layer for use as a capacitor electrode in a DRAM device may be used.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a repair fuse over a substrate;
forming an insulation layer over the repair fuse and the substrate;
forming a metal line for use as a pad over the insulation layer, the metal line including a first metal layer and a second metal layer in a stack structure;
forming a passivation layer over the substrate structure;
forming a mask pattern for forming a pad open region and a fuse open region;
etching the passivation layer and the insulation layer using a gas mixture that causes the insulation layer to remain over the repair fuse with a predetermined thickness and generates a polymer over the second metal layer;
removing the polymer; and
etching the second metal layer.

2. The method of claim 1, wherein the mask pattern comprises a photoresist pattern.

3. The method of claim 2, further comprising, after etching the second metal layer, removing the photoresist pattern and performing a cleaning process.

4. The method of claim 2, wherein removing the polymer further comprises removing the photoresist pattern.

5. The method of claim 1, wherein the insulation layer comprises an oxide-based material, and the passivation layer comprises a stack structure including an oxide-based material and a nitride-based material.

6. The method of claim 5, wherein the gas mixture comprises tetrafluoromethane (CF₄), fluoroform (CHF₃), and argon (Ar).

7. The method of claim 6, wherein the gas mixture comprises a ratio of CF₄ to CHF₃ that is less than approximately 4:1.

8. The method of claim 1, wherein the gas mixture has a high carbon/fluorine ratio.

9. The method of claim 8, wherein the gas mixture comprises one of C₄F₈ and C₄F₆.

10. The method of claim 1, wherein the second metal layer comprises titanium nitride (TiN).

11. The method of claim 10, wherein etching the second metal layer comprises supplying a gas including chlorine (Cl₂).

12. The method of claim 11, wherein the gas including Cl₂ comprises one of Cl₂/trichloroborane (BCl₃) gas and Cl₂/Ar gas.

13. The method of claim 1, wherein removing the polymer comprises performing a plasma etching using a gas including oxygen (O₂).

14. The method of claim 1, wherein the first metal layer comprises aluminum (Al).

15. The method of claim 1, wherein the metal line comprises an upper metal line, and the repair fuse comprises a metal layer for use as a bottom metal line.
